(19) United States
(12) Patent Application Publication
(10) Pub. No.: US 2026/0038616 A1
(43) Pub. Date: Feb. 5, 2026

(54) MEMORY SUB-SYSTEM FOR BLOCK STRIPE SELECTION AND TESTING

(71) Applicant: Micron Technology, Inc., Boise, ID (US)

(72) Inventors: Juane Li, San Jose, CA (US); Steven Narum, Meridian, ID (US)

(21) Appl. No.: 18/789,610

(22) Filed: Jul. 30, 2024

(51) Int. Cl. G11C 29/10

(52) U.S. Cl. CPC G11C 29/10

(57) ABSTRACT

Various aspects of the present disclosure relate to a memory sub-system for block stripe selection and testing. A processing device determines to perform a test for a subset of block stripes of a plurality of block stripes of the memory device, where each block stripe of the plurality of block stripes spans the plurality of dies of the memory device, and the subset of block stripes includes less than all block stripes of the plurality of block stripes. The processing device obtains a first parameter that indicates a first block stripe to be tested and a second parameter that indicates a quantity of block stripes to be tested. The processing device initiates and performs the test for the subset of block stripes using the first parameter and the second parameter.

### TECHNICAL FIELD

Aspects of the disclosure relate generally to memory sub-systems, and more specifically, to a memory sub-system for block stripe testing.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various aspects of the disclosure.

FIG. 1 illustrates an example computing system that includes a memory sub-system, in accordance with some aspects of the present disclosure.

FIG. 2 is a diagram illustrating an example method of block skewing, in accordance with some aspects of the present disclosure.

FIGS. 3A-3B are diagrams illustrating an example method of block stripe selection and

testing, in accordance with some aspects of the present disclosure.

FIG. 4 is a flow diagram of an example method of block stripe selection and testing, in accordance with some aspects of the present disclosure.

FIG. 5 is a block diagram of an example computer system in which some aspects of the present disclosure may operate.

### DETAILED DESCRIPTION

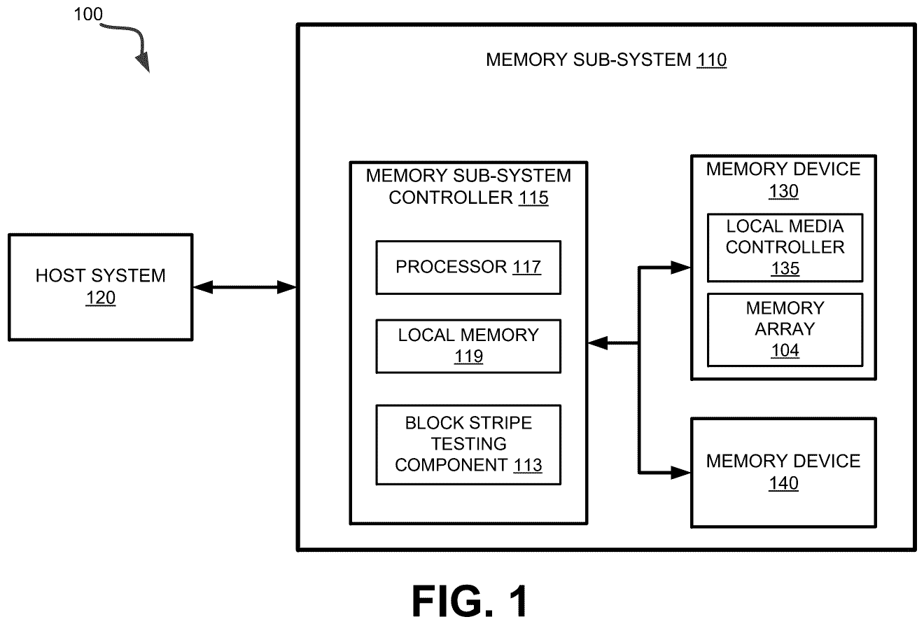

Aspects of the present disclosure are directed to a memory sub-system for block stripe selection and testing. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not- and (NAND) memory device. Other examples of non-volatile memory devices are described below in conjunction with FIG. 1. A non-volatile memory device is a package of one or more dies. Each die can include one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can include multiple memory cells arranged in a two-dimensional or a three-dimensional grid. Memory cells are formed onto a silicon wafer in a rectangular array; the memory cells may be joined by conductive lines referred to as wordlines and bitlines. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For case of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

A memory device may include one or more dies. In some examples, each memory device in a memory sub-system corresponds to a single die of the memory sub-system. In some other examples, each memory device in the memory sub-system can include multiple dies of the memory sub-system. Data can be stored in a memory device using block stripes, where each block stripe includes multiple data blocks and spans multiple dies (for example, all dies) of the memory device. Therefore, a block stripe may include at least one block from each plane of the memory device and across all dies of the memory device. In some cases, a block stripe may include one or more bad blocks. A bad block is a block that is associated with an error condition. For example, a bad block may result from a manufacturing defect or physical damage to the memory device. The memory device may be able to be used even if the memory device includes a certain number of bad blocks. However, an increase in the number of bad blocks may result in an increased likelihood that the memory device will fail or need to be discarded.

A block stripe may be tested to ensure the integrity of data stored in the blocks of the block stripe, to validate a performance of the block stripe, or to detect signs of wear or potential failure of the block stripe, among other examples. Testing the block stripe may include writing test data to the blocks of the block stripe, and subsequently reading the test data from the blocks of the block stripe to detect any discrepancies between the data that was written and the data that was read back. A block having a discrepancy count that is greater than a discrepancy count threshold may be considered to be a bad block. In some cases, all blocks (for example, all block stripes) of the memory device may be tested using a single test. This may be referred to as full stroke testing. Testing all blocks of the memory device using a single test may reduce a likelihood of errors in the blocks of the memory device. However, full stroke testing may require significant time and processing resources to be performed. In some other cases, only some of the blocks (for example, a subset of the block stripes) of the memory device may be tested during a single test. This may be referred to as short stroke testing. For example, a short stroke test may include testing ten percent of the blocks of the memory device. In this example, only ten percent of the drive may be made available to the host for testing. This may reduce a duration of the test and a quantity of processing resources that are needed to perform the test.

Block skewing refers to a process of accessing and testing memory blocks in a non-sequential or staggered manner across different dies of a memory device. In some cases, block skewing may be used to evenly distributing bad blocks in the memory device into block stripes. Block skewing may be used to identify and mitigate performance bottlenecks and reliability issues that may not be easily detectable when testing blocks sequentially. Block skewing may include implementing non-sequential access of the memory blocks. Instead of accessing memory blocks in a linear, sequential order (e.g., block 0, block 1, and block 2 on plane 0 of die 0), block skewing may involve accessing blocks in a staggered or skewed order (e.g., block 0 on plane 0 of die 0, block 1 on plane 1 of die 1, and block 2 on plane 2 of block 2). This may improve a likelihood that memory operations are spread across different physical locations within the device, simulating more realistic usage patterns. Additionally, block skewing can facilitate concurrent access and testing of multiple blocks across different dies, which may assist in evaluating an ability of the memory device to handle parallel operations. This is particularly important in multi-die memory devices, where inter-die communication and synchronization can impact overall performance.

In some cases, performance requirements for a memory device may require that blocks to be tested are distributed across a memory device. For example, the performance requirements for a short stroke test may require that the test includes blocks that are evenly distributed on a die (for example, on a top, middle, and bottom portion of the die) and that the test covers all planes. However, some block skewing methods may not satisfy these performance requirements. For example, a short stroke test with block skewing may be used to test a top portion of the die, a middle portion of the die, or a bottom portion of the die. Therefore, results of the block testing may show an uneven distribution of errors, for example, since the top portion and the bottom portion of the die is more likely to have errors than the middle portion of the die.

Aspects of the present disclosure address the above and other deficiencies by implementing a memory sub-system for block stripe selection and testing. A memory sub-system controller, coupled with a memory device that includes a plurality of dies and a plurality of block stripes, may determine to perform a test for a subset of block stripes of the plurality of block stripes. In some aspects, the test may be a short stroke test. For example, the test may be a short stroke test for testing an end-of-life behavior of the memory device. The subset of block stripes may include less than all block stripes of the plurality of block stripes of the memory device. The memory sub-system controller may obtain a first parameter that indicates a first block stripe of the plurality of block stripes to be tested. In some aspects, the memory sub-system controller may obtain the first parameter by generating a random number that corresponds to an identifier of the first block stripe to be tested. Additionally, the memory sub-system controller may obtain a second parameter that indicates a quantity of block stripes to be tested. For example, the second parameter may indicate the quantity of block stripes to be included in the subset of block stripes. The memory sub-system controller may initiate the test for the subset of block stripes using the first parameter and the second parameter. In one example, the first block stripe may be indicated by y (for example, 11) and the quantity of block stripes may be indicated by n (for example, 4). In this example, the memory sub-system controller, to initiate and perform the test for the subset of block stripes, may initiate and perform the test for all block stripes included in a range of block stripes from y to y+n−1 (for example, block stripes 11 through 14).

Some advantages of the present disclosure include improved block stripe testing for a subset of block stripes of a memory device. Some advantages of the present disclosure include enabling a block stripe test (for example, a short stroke test) to test blocks of the memory device that are evenly distributed on a die and that are evenly distributed across all planes of the die. Some advantages of the present disclosure include enabling an even distribution of errors resulting from the block stripe test. For example, some advantages of the present disclosure include enabling an error distribution that is evenly distributed across a top portion of the die, a middle portion of the die, and a bottom portion of the die. Some advantages of the present disclosure include increasing a speed and accuracy of the block stripe test while reducing a quantity of processing resources that are needed for performing the block stripe test. Some advantages of the present disclosure include decreasing a complexity for block stripe testing. For example, some advantages of the present disclosure include enabling changing of the block stripes to be tested by changing a value of a parameter corresponding to the first block stripe to be included in the test. Some advantages of the present disclosure include eliminating the need for a dedicated block stripe selection rule for short stroke testing. For example, some advantages of the present disclosure include enabling the same block skewing process to be used for short stroke tests and full stroke tests. Some advantages of the present disclosure include enabling the pooling of multiple short stroke tests together, thereby enabling all block stripes of the memory device to be tested over time for each plane and for each die. These example advantages, among others, are described in more detail below.

FIG. 1 illustrates an example computing system 100 that includes a memory sub-system 110, in accordance with some aspects of the present disclosure. The memory sub-system 110 can include media, such as one or more volatile memory devices (e.g., memory device 140), one or more non-volatile memory devices (e.g., one or more memory device(s) 130), or a combination of such.

The memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some aspects, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., the one or more memory device(s) 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be random access memory (RAM), such as dynamic random access memory (DRAM) and synchronous dynamic random access memory (SDRAM).

Some examples of non-volatile memory devices (e.g., memory device(s) 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory device(s) 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some aspects, each of the memory devices 130 can include one or more arrays of memory cells such as SLCs, MLCs, TLCs, QLCs, or any combination of such. In some aspects, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 115 (or controller 115 for simplicity) can communicate with the memory device(s) 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some aspects, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in some other aspects, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device(s) 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory device(s) 130. The memory sub-system controller 115 can further include host interface circuitry to communicate with the host system 120 via the physical host interface. The host interface circuitry can convert the commands received from the host system into command instructions to access the memory device(s) 130 as well as convert responses associated with the memory device(s) 130 into information for the host system 120.

The memory sub-system 110 can also include additional circuitry or components that are not illustrated. In some aspects, the memory sub-system 110 can include a cache or buffer (e.g., DRAM) and address circuitry (e.g., a row decoder and a column decoder) that can receive an address from the memory sub-system controller 115 and decode the address to access the memory device(s) 130.

In some aspects, the memory device(s) 130 include local media controllers 135 that operate in conjunction with memory sub-system controller 115 to execute operations on one or more memory cells of the memory device(s) 130. An external controller (e.g., memory sub-system controller 115) can externally manage the memory device 130 (e.g., perform media management operations on the memory device(s) 130). In some aspects, a memory device 130 is a managed memory device, which is a raw memory device (e.g., memory array 104) having control logic (e.g., local controller 135) for media management within the same memory device package. An example of a managed memory device is a managed NAND (MNAND) device. Memory device(s) 130, for example, can each represent a single die having some control logic (e.g., local media controller 135) embodied thereon. In some aspects, one or more components of memory sub-system 110 can be omitted.

In some aspects, the memory sub-system 110 includes a block stripe testing component 113 that can be used to perform block stripe selection and testing. For example, the block stripe testing component 113 may perform a test, such as a short stroke test, to test a subset of block stripes of a plurality of block stripes of a memory device. In some aspects, the block stripe testing component 113 obtains a first parameter that indicates a first block stripe to be tested. The block stripe testing component 113 may obtain the first parameter by generating a random number that corresponds to an identifier of the first block stripe to be tested. Additionally, the block stripe testing component 113 obtains a second parameter that indicates a quantity of block stripes to be tested. For example, the second parameter may indicate the quantity of block stripes to be included in the subset of block stripes. The block stripe testing component 113 initiates the test for the subset of block stripes using the first parameter and the second parameter. In one example, the first block stripe may be indicated by y (for example, 11) and the quantity of block stripes may be indicated by n (for example, 4). In this example, the block stripe testing component 113, to initiate and perform the test for the subset of block stripes, may initiate and perform the test for all block stripes included in a range of block stripes from y to y+n−1 (for example, block stripes 11 through 14). Additional details regarding these features are described below.

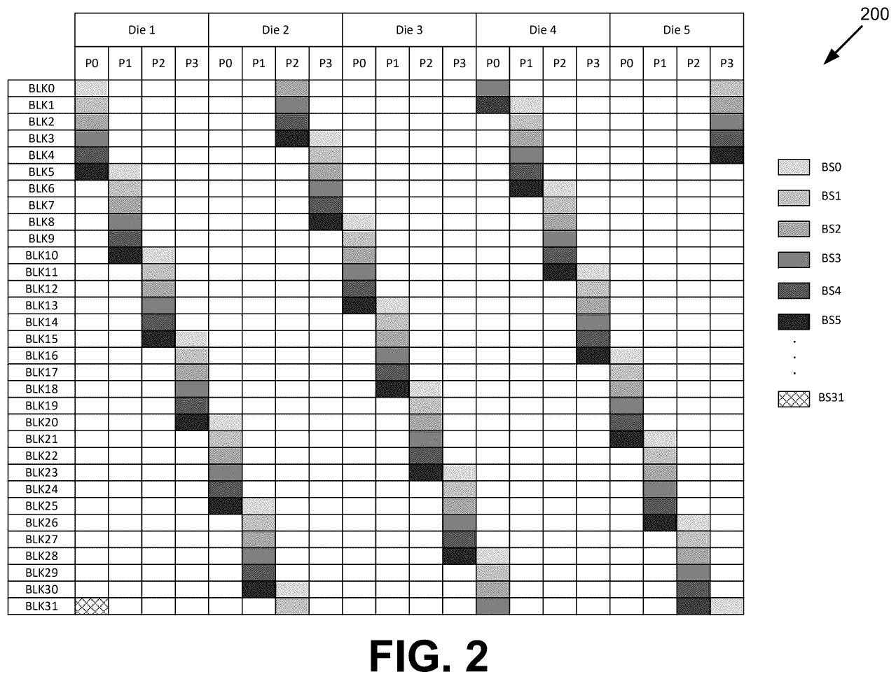

FIG. 2 is a diagram illustrating an example method 200 of block skewing, in accordance with some aspects of the present disclosure.

A memory device includes multiple dies. For example, the memory device may include five dies labeled as Die 1, Die 2, Die 3, Die 4, and Die 5. Additionally, the memory device includes multiple planes. For example, the memory device may include four planes labeled as P0, P1, P2, and P3. Each plane is uniformly distributed across each die, meaning that every die includes all four planes. Further, the memory device includes multiple blocks. For example, the memory device may include thirty-two blocks labeled as BLK0 through BLK31. Each block is distributed across each of the five dies and spans all four planes within each die. Therefore, each block is spread across multiple planes in every die, creating a robust framework for data storage. This block structure ensures that data within a block is distributed across the entire memory device, enhancing the ability to perform parallel operations, and improving overall data management efficiency.

In some cases, the memory device includes multiple block stripes. Each block stripe of the multiple block stripes spans all dies of the memory device and all planes of the memory device. For example, the memory device may include thirty-two block stripes labeled as BS0 through BS31. While the number of block stripes in this example corresponds to the number of blocks of the memory device, in other examples, the number of block stripes may be different than the number of blocks of the memory device. In some cases, the block stripes may be distributed across all dies and all planes of the memory device in accordance with a block skewing offset value. In the example 200, the block skewing offset value is equal to five. Therefore, each block stripe spans the multiple planes and die of the memory device and includes every fifth block of the memory device. For example, a first block stripe (BS0) may include BLK0 of P0 of Die 1, BLK5 of P1 of Die 1, BLK10 of P2 of Die 1, BLK15 of P3 of Die 1, BLK20 of P0 of Die 2, BLK25 of P1 of Die 2, BLK 30 of P2 of Die 2, BLK3 of P3 of Die 2, BLK8 of P0 of Die 3, BLK13 of P1 of Die 3, etc.

In some cases, a block skewing operation may include skewing across a range of blocks. For example, the multiple blocks of the memory device may be separated into multiple ranges of consecutive blocks. A first range of blocks may include BLK0 through BLK7, a second range of blocks may include BLK8 through BLK15, a third range of blocks may include BLK16 through BLK23, and a fourth range of blocks may include BLK24 through BLK31. The ranges of blocks may be spread across all dies and all planes of the memory device. When performing a test for the block stripes, such as a short stroke test, a memory sub-system controller may select a range of blocks on which the test is to be performed. However, the different ranges of blocks may include different quantities of errors. For example, the first range of blocks, which includes the top portion of the die, and the fourth range of blocks, which includes the bottom portion of the die, may include more errors (more bad blocks) than the second range of blocks and the third range of blocks, which include the middle portion of the die. This may lead to an uneven distribution of bad blocks, thereby resulting in test results that are less reliable, for example, compared to full stroke test results.

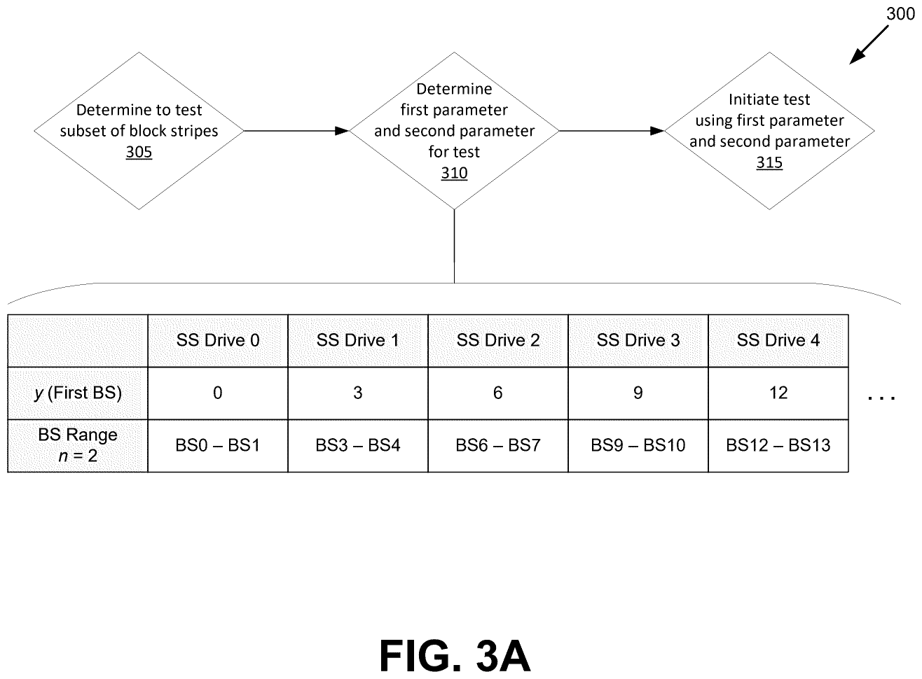

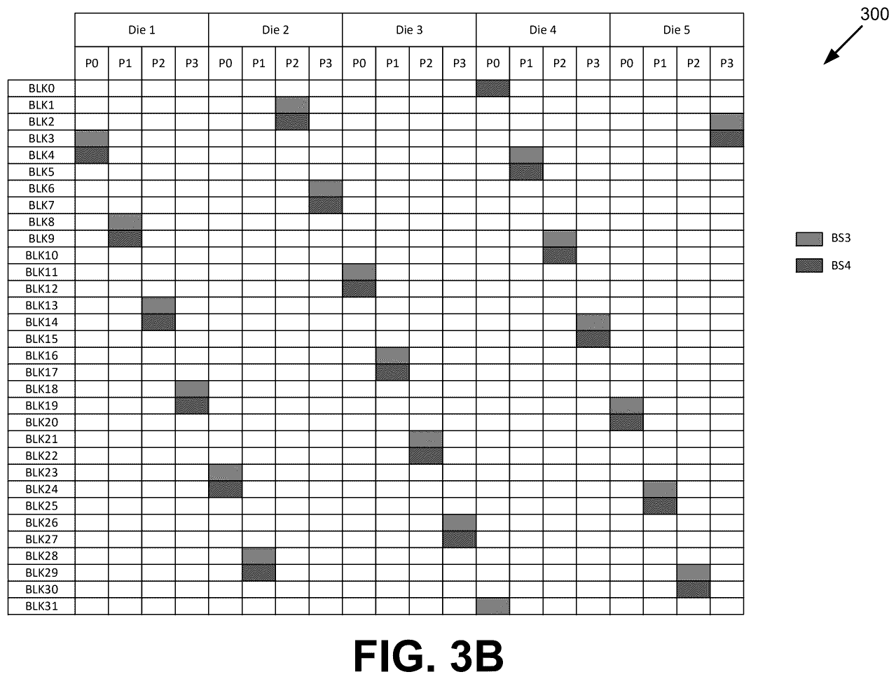

FIGS. 3A-3B are diagrams illustrating an example method 300 of block stripe selection and testing, in accordance with some aspects of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some aspects, the method 300 is performed by the block stripe testing component 113 of FIG. 1. Although shown in a particular sequence or order, unless otherwise specified, the order of the processes can be modified. Thus, the illustrated aspects should be understood only as examples, and the illustrated processes can be performed in a different order, and some processes can be performed in parallel. Additionally, one or more processes can be omitted in various aspects. Thus, not all processes are required in every aspect. Other process flows are possible.

At operation 305, the processing logic determines to test a subset of block stripes. The subset of block stripes may be a portion (less than all) of block stripes of a plurality of block stripes of a memory device. In some aspects, the processing logic may receive a request to perform the test for the subset of block stripes of the memory device. For example, the processing logic may receive a request from a host system to perform the test for the subset of block stripes of the memory device. In some other aspects, the processing logic may determine to perform the test for the subset of block stripes based on one or more conditions of the memory device, such as based on a testing interval or a number of bad blocks in the memory device, among other examples.

In some aspects, to determine to test the subset of block stripes of the memory device, the processing logic may determine to perform a short stroke (SS) test for the memory device. For example, the processing logic may determine to perform a short stroke for the memory device using one or more short stroke drives. A short stroke drive may be used to test a percentage of the memory device capacity. For example, for a ten percent short stroke test, only ten percent of the memory device capacity is made visible to the host system. In some aspects, short stroke drive testing may be used to test an end-of-life behavior of the memory device.

At operation 310, the processing logic determines a first parameter and a second parameter for performing the test. The first parameter, which is represented by the variable y, indicates a first block stripe that is to be tested. In some aspects, determining the first parameter may include generating a random number that indicates the first block stripe to be tested. For example, if the random number generation results in the value 3, the processing logic may begin the test at block stripe 3 (BS3). The second parameter, which is represented by the variable n, indicates a quantity of block stripes that are to be tested. For example, a value of four indicates that four block stripes are to be tested during each iteration of the test. Therefore, the number of block stripes in the subset of block stripes may correspond to the value of n.

In some aspects, determining the first parameter and the second parameter may include selecting a short stroke drive from a plurality of candidate short stroke drives. Each short stroke drive of the plurality of candidate short stroke drives may indicate a first block stripe to be tested (for example, based on the value of y) and a quantity of block stripes to be tested (for example, based on the value of n). As shown in the figure, a first short stroke drive (SS Drive 0) may begin at BS0 and may test BS0 and BS1 (y=0, n=2), a second short stroke drive (SS Drive 1) may begin at BS3 and may test BS3 and BS4 (y=3, n=2), a third short stroke drive (SS Drive 2) may begin at BS6 and may test BS6 and BS7 (y=6, n=2), a fourth short stroke drive (SS Drive 3) may begin at BS9 and may test BS9 and BS10 (y=9, n=2), and a fifth short stroke drive (SS Drive 4) may begin at BS12 and may test BS12 and BS13 (y=12, n=2). In some aspects, the second parameter may be the same for all short stroke drives. For example, the value of n may be the same across all short stroke drives. In some other aspects, the second parameter may be different for at least two short stroke drives of the plurality of short stroke drives. The short stroke drives shown in FIG. 3A are provided for example only. For example, the processing logic may select a short stroke drive from any number of candidate short stroke drives.

In one example, for each short stroke drive, ten percent of the block stripes of the memory device may be tested. However, the actual block stripes being tested may be different for each short stroke drive. This may be achieved by adding the second parameter (y) which serves as an offset for the first block stripe to be tested in each short stroke drive. The second parameter may have a starting block index on plane 0 (P0) of die 0. Therefore, SS Drive 0 may include block stripes BS (y0), BS (y0+1), BS (y0+2), . . . , and BS (y0+n−1), where y0 is the first block stripe for SS Drive 0 and n is the number of block stripes to be used for the SS drive. Additionally, SS Drive 1 may include block stripes BS (y1), BS (y1+1), BS (y1+2), . . . , and BS (y1+n−1), where y1 is the first block stripe for SS Drive 1 and where n is the number of block stripes to be used for the SS drive. In some aspects, performance requirements may require that short stroke drive firmware select blocks that distribute evenly on a die (for example, on the top, middle, and bottom of the die) and that cover all planes of the die to ensure coverage of all physical corners of the die. A short stroke drive pool that includes all of the candidate short stroke drives may enable the processing logic to test every single block for each plane and die of the memory device. Therefore, the performance requirements may be satisfied.

At operation 315, the processing logic initiates the test using the first parameter and the second parameter. In one example, the processing logic may initiate the test using a first parameter having a value of three (y=3) and a second parameter having a value of two (n=2). Therefore, the processing logic may begin the test at BS3 and may test two block stripes beginning with BS3. Additional details are described below.

As shown in FIG. 3B, the processing logic performs the test for the subset of block stripes based on the first parameter and the second parameter. For example, the processing logic may perform the test for the subset of block stripes of SS Drive 1, with a first parameter value of three (y=3) and a second parameter value of two (n=2). To perform the rest for the subset of block stripes based on the first parameter having the value of three and the second parameter having the value of two, the processing logic may perform the test for two block stripes beginning at BS3. Therefore, the processing logic may perform the test for BS3 and BS4. As shown, the processing logic performs the test (for example, the short stroke test) for BLK3 and BLK4 on P0 of Die 1, BLK8 and BLK8 on P1 of Die 1, BLK13 and BLK14 on P2 of Die 1, BLK18 and BLK19 on P3 of Die 1, BLK23 and BLK24 on P0 of Die 2, BLK28 and BLK29 on P1 of Die 2, BLK1 and BLK2 on P2 of Die 2, BLK6 and BLK7 on P3 of Die 2, BLK11 and BLK12 on P0 of Die 3, BLK16 and BLK17 on P1 of Die 3, BLK21 and BLK22 on P2 of Die 3, BLK26 and BLK27 on P3 of Die 3, BLK0 and BLK31 on P0 of Die 4, BLK4 and BLK5 on P1 of Die 4, BLK9 and BLK10 on P2 of Die 4, BLK15 and BLK16 on P3 of Die 4, BLK19 and BLK20 on P0 of Die 5, BLK24 and BLK25 on P1 of Die 5, BLK29 and BLK30 on P2 of Die 5, and BLK2 and BLK3 on P3 of Die 5. By performing the short stroke test as described herein, the block stripes may be tested across all planes and all dies of the memory device, thereby improving accuracy of short stroke testing while maintaining shorter testing times and reduced processing requirements compared to full stroke testing.

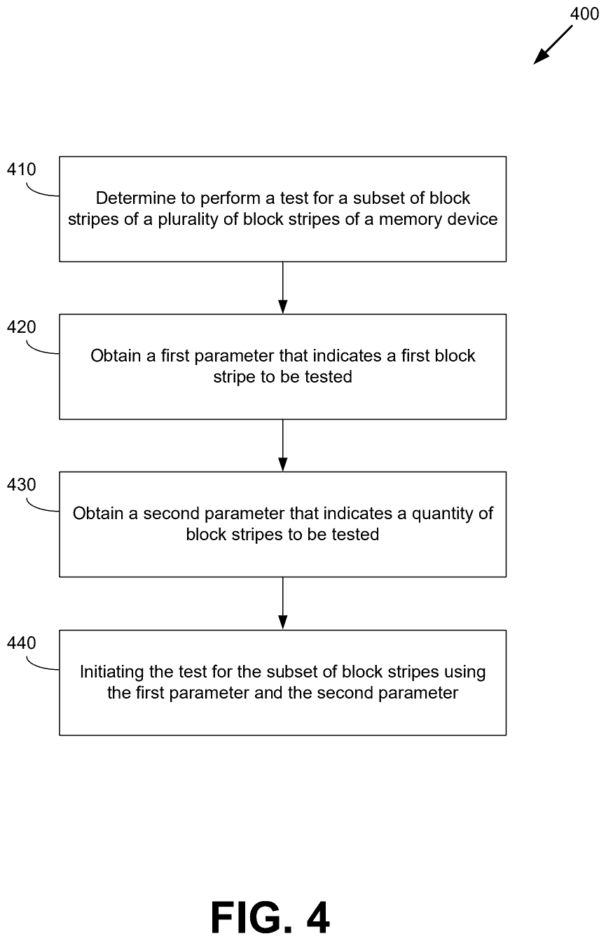

FIG. 4 is a flow diagram of an example method 400 of block stripe selection and testing, in accordance with some aspects of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some aspects, the method 400 is performed by the block stripe testing component 113 of FIG. 1. Although shown in a particular sequence or order, unless otherwise specified, the order of the processes can be modified. Thus, the illustrated aspects should be understood only as examples, and the illustrated processes can be performed in a different order, and some processes can be performed in parallel. Additionally, one or more processes can be omitted in various aspects. Thus, not all processes are required in every aspect. Other process flows are possible.

At operation 410, the processing logic determines to perform a test for a subset of block stripes of a plurality of block stripes of a memory device. Each block stripe of the plurality of block stripes spans the plurality of dies of the memory device. The subset of block stripes includes less than all block stripes of the plurality of block stripes. In some implementations, the test for the subset of block stripes is a short stroke test associated with an end of life behavior of the memory device.

At operation 420, the processing logic obtains a first parameter that indicates a first block stripe to be tested. In some implementations, obtaining the first parameter comprises generating a random number that corresponds to an identifier of the first block stripe.

At operation 430, the processing logic obtains a second parameter that indicates a quantity of block stripes to be tested.

At operation 440, the processing logic initiates the test for the subset of block stripes using the first parameter and the second parameter. In some implementations, each block stripe of the subset of block stripes includes multiple blocks that are evenly distributed on the memory device and that cover all planes of the memory device.

In some implementations, the first block stripe is y and the quantity of block stripes is n, and the processing device, to initiate the test for the subset of block stripes using the first parameter and the second parameter, is configured to initiate the test for all block stripes included in a range of block stripes from y to y+n−1. In some implementations, the test for the subset of block stripes is included in a plurality of candidate tests, the plurality of candidate tests comprising at least a first test associated with a first subset of block stripes that begins with the first block stripe and includes the quantity of block stripes and a second test associated with a second subset of block stripes that begins with a second block stripe and that includes the quantity of block stripes. In some implementations, each candidate test of the plurality of candidate tests uses a same block skewing parameter.

In some implementations, a non-transitory computer-readable storage medium comprises instructions that, when executed by a processing device, cause the processing device to perform one or more operations of the method 400.

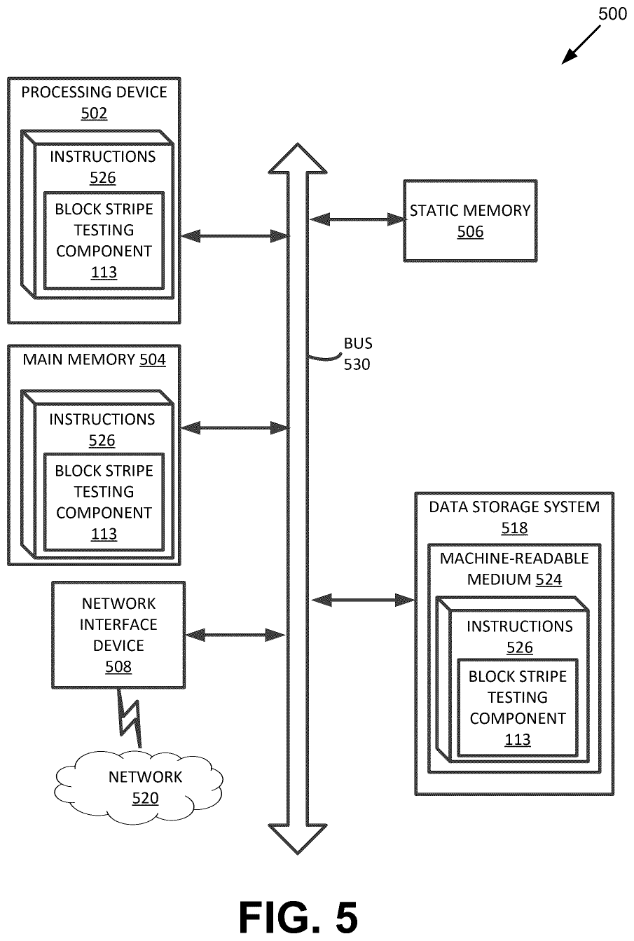

FIG. 5 illustrates an example machine of a computer system 500 within which a set of instructions, for causing the machine to perform any one or more of the methodologies discussed herein, can be executed. In some aspects, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the block stripe testing component 113 of FIG. 1). In alternative aspects, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In some aspects, the instructions 526 include instructions to implement functionality corresponding to the data migration component 113 of FIG. 1). While the machine-readable storage medium 524 is shown in an example aspect to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, which manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, which can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some aspects, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, aspects of the disclosure have been described with reference to specific example aspects thereof. It will be evident that various modifications can be made thereto without departing from the broader spirit and scope of aspects of the disclosure as set forth in the following claims. The specification and drawings are, accordingly, to be regarded in an illustrative sense rather than a restrictive sense.

What is claimed is:

1. A system comprising:
a memory device comprising a plurality of dies; and
a processing device, coupled with the memory device, configured to perform operations comprising:
determining to perform a test for a subset of block stripes of a plurality of block stripes of the memory device, wherein each block stripe of the plurality of block stripes spans the plurality of dies of the memory device, and wherein the subset of block stripes includes less than all block stripes of the plurality of block stripes;
obtaining a first parameter that indicates a first block stripe to be tested;
obtaining a second parameter that indicates a quantity of block stripes to be tested; and
initiating the test for the subset of block stripes using the first parameter and the second parameter.

2. The system of claim 1, wherein the first block stripe is y and the quantity of block stripes is n, and wherein the processing device, to initiate the test for the subset of block stripes using the first parameter and the second parameter, is configured to initiate the test for all block stripes included in a range of block stripes from y to y+n−1.

3. The system of claim 1, wherein obtaining the first parameter comprises generating a random number that corresponds to an identifier of the first block stripe.

4. The system of claim 1, wherein each block stripe of the subset of block stripes includes multiple blocks that are evenly distributed on the memory device and that cover all planes of the memory device.

5. The system of claim 1, wherein the test for the subset of block stripes is included in a plurality of candidate tests, the plurality of candidate tests comprising at least a first test associated with a first subset of block stripes that begins with the first block stripe and includes the quantity of block stripes and a second test associated with a second subset of block stripes that begins with a second block stripe and that includes the quantity of block stripes.

6. The system of claim 5, wherein each candidate test of the plurality of candidate tests uses a same block skewing parameter.

7. The system of claim 1, wherein the test for the subset of block stripes is a short stroke test associated with an end of life behavior of the memory device.

8. A method comprising:
determining to perform a test for a subset of block stripes of a plurality of block stripes of a memory device, wherein each block stripe of the plurality of block stripes spans a plurality of dies of the memory device, and wherein the subset of block stripes includes less than all block stripes of the plurality of block stripes;
obtaining a first parameter that indicates a first block stripe to be tested;
obtaining a second parameter that indicates a quantity of block stripes to be tested; and
initiating the test for the subset of block stripes using the first parameter and the second parameter.

9. The method of claim 8, wherein the first block stripe is y and the quantity of block stripes is n, and wherein initiating the test for the subset of block stripes using the first parameter and the second parameter comprises initiating the test for all block stripes included in a range of block stripes from y to y+n−1.

10. The method of claim 8, wherein obtaining the first parameter comprises generating a random number that corresponds to an identifier of the first block stripe.

11. The method of claim 8, wherein each block stripe of the subset of block stripes includes multiple blocks that are evenly distributed on the memory device and that cover all planes of the memory device.

12. The method of claim 8, wherein the test for the subset of block stripes is included in a plurality of candidate tests, the plurality of candidate tests comprising at least a first test associated with a first subset of block stripes that begins with the first block stripe and includes the quantity of block stripes and a second test associated with a second subset of block stripes that begins with a second block stripe and that includes the quantity of block stripes.

13. The method of claim 12, wherein each candidate test of the plurality of candidate tests uses a same block skewing parameter.

14. The method of claim 8, wherein the test for the subset of block stripes is a short stroke test associated with an end of life behavior of the memory device.

15. A non-transitory computer-readable storage medium comprising instructions that, when executed by a processing device, cause the processing device to perform operations comprising:
determining to perform a test for a subset of block stripes of a plurality of block stripes of a memory device, wherein each block stripe of the plurality of block stripes spans a plurality of dies of the memory device, and wherein the subset of block stripes includes less than all block stripes of the plurality of block stripes;
obtaining a first parameter that indicates a first block stripe to be tested;
obtaining a second parameter that indicates a quantity of block stripes to be tested; and
initiating the test for the subset of block stripes using the first parameter and the second parameter.

16. The non-transitory computer-readable storage medium of claim 15, wherein the first block stripe is y and the quantity of block stripes is n, and wherein initiating the test for the subset of block stripes using the first parameter and the second parameter comprises initiating the test for all block stripes included in a range of block stripes from y to y+n−1.

17. The non-transitory computer-readable storage medium of claim 15, wherein obtaining the first parameter comprises generating a random number that corresponds to an identifier of the first block stripe.

18. The non-transitory computer-readable storage medium of claim 15, wherein each block stripe of the subset of block stripes includes multiple blocks that are evenly distributed on the memory device and that cover all planes of the memory device.

19. The non-transitory computer-readable storage medium of claim 15, wherein the test for the subset of block stripes is included in a plurality of candidate tests, the plurality of candidate tests comprising at least a first test associated with a first subset of block stripes that begins with the first block stripe and includes the quantity of block stripes and a second test associated with a second subset of block stripes that begins with a second block stripe and that includes the quantity of block stripes.

20. The non-transitory computer-readable storage medium of claim 19, wherein each candidate test of the plurality of candidate tests uses a same block skewing parameter.
